(19) United States
(12) Patent Application Publication
(10) Pub. No.: US 2025/0113693 A1
(43) Pub. Date: Apr. 3, 2025

(54) Display Panel and Manufacturing Method Therefor, and Display Device

(71) Applicant: BOE Technology Group Co., Ltd., Beijing (CN)

(72) Inventors: Haixu LI, Beijing (CN); Zhanfeng CAO, Beijing (CN); Xinxin ZHAO, Beijing (CN)

(21) Appl. No.: 18/294,552

(22) PCT Filed: Aug. 31, 2022
(86) PCT No.: PCT/CN2022/116114

§ 371 Date: Feb. 2, 2024

(51) Int. Cl. H10H 29/855; H10H 29/01; H10H 29/851; H10H 29/854

(52) U.S. Cl. CPC H10H 29/8552; H10H 29/8512; H10H 29/854; H10H 29/0363

(57) ABSTRACT

A display panel, a manufacturing method therefor and a display device are provided. The display panel includes a drive backplate; at least one light emitting unit disposed on the drive backplate; a support structure disposed on the drive backplate, wherein an orthographic projection of the support structure on the drive backplate is not overlapped with an orthographic projection of the at least one light emitting unit on the drive backplate; a light shielding layer disposed on the drive backplate, wherein the light shielding layer covers at least part of the support structure and an orthographic projection of the light shielding layer on the drive backplate is not overlapped with the orthographic projection of the at least one light emitting unit on the drive backplate.

### CROSS-REFERENCE TO RELATED APPLICATION

The present application is a U.S. National Phase Entry of International Application PCT/CN2022/116114 having an international filing date of Aug. 31, 2022, and entitled “Display Panel and Manufacturing Method therefor, and Display Device”, the contents of which are hereby incorporated herein by reference in their entireties.

### TECHNICAL FIELD

The present disclosure relates to, but is not limited to the field of display technologies, in particular to a display panel and a method for manufacturing the display panel, and a display device.

### BACKGROUND

Semiconductor Light Emitting Diode (LED for short) technologies have been under development for nearly 30 years, from an initial solid-state lighting power supply to a backlight source in the field of display, and then to an LED display screen, providing a solid foundation for its wider applications.

Micro LED is a display technology, which makes a conventional LED structure miniaturized and matrixing, and adopts integrated circuit technology to make a drive circuit to realize addressing control and individual drive of each pixel point. Micro LED technology is regarded as a next generation display technology because its brightness, service life, contrast, reaction time, energy consumption, viewing angle, resolution, etc., are superior to those of LCD (Liquid Crystal Display) technology and OLED (Organic Light Emitting Diode) technology, plus its advantages of self-luminescence, simple structure, small size and energy saving, and leading enterprises of display technologies have begun active planning on Micro LED.

### SUMMARY

The following is a summary of subject matters described herein in detail. The summary is not intended to limit the scope of protection of the claims.

In a first aspect, an embodiment of the present disclosure provides a display panel, which includes:
a drive backplate;
at least one light emitting unit disposed on the drive backplate;
a support structure, disposed on the drive backplate, wherein an orthographic projection of the support structure on the drive backplate is not overlapped with an orthographic projection of the at least one light emitting unit on the drive backplate; and
a light shielding layer disposed on the drive backplate, wherein the light shielding layer covers at least part of the support structure and an orthographic projection of the light shielding layer on the drive backplate is not overlapped with the orthographic projection of the at least one light emitting unit on the drive backplate.

In an exemplary implementation, the support structure has a side surface and a first top surface and the light shielding layer covers the side surface and the first top surface of the support structure.

In an exemplary implementation, the light shielding layer has a second top surface and the second top surface is on a side of the first top surface away from the drive backplate.

In an exemplary implementation, a distance between the second top surface and the first top surface is 1 micron to 2 microns.

In an exemplary implementation, the support structure has a first top surface, the at least one light emitting unit has a third top surface, and the first top surface is on a side of the third top surface away from the drive backplate.

In an exemplary implementation, an outer profile of a vertical cross section of the light shielding layer is narrower at the top and wider at the bottom.

In an exemplary implementation, a cell-alignment substrate is further included and the cell-alignment substrate is disposed on a side of the at least one light emitting unit away from the drive backplate.

In an exemplary implementation, the cell-alignment substrate includes a light blocking pattern and the orthographic projection of the support structure on the drive backplate is overlapped with an orthographic projection of the light blocking pattern on the drive backplate.

In an exemplary implementation, the cell-alignment substrate further includes a color conversion pattern, an orthographic projection of the color conversion pattern on the drive backplate is not overlapped with the orthographic projection of the light blocking pattern on the drive backplate, and the orthographic projection of the color conversion pattern on the drive backplate is overlapped with the orthographic projection of the light emitting unit on the drive backplate.

In an exemplary implementation, the color conversion pattern includes a quantum dot material or a fluorescent material.

In an exemplary implementation, an encapsulation layer is further included, the encapsulation layer is disposed on the drive backplate, and the encapsulation layer covers at least a part of the at least one light emitting unit.

In an exemplary implementation, the encapsulation layer includes a thermally conductive material.

In an exemplary implementation, at least one support post is further included, the at least one support post is on a side of the support structure away from the drive backplate, and an orthographic projection of the at least one support post on the drive backplate is overlapped with the orthographic projection of the at least one light emitting unit on the drive backplate.

In an exemplary implementation, the support structure has a first top surface, the light shielding layer covers the first top surface of the support structure, the light shielding layer has a second top surface, and the at least one support post is disposed on the second top surface.

In an exemplary implementation, a distance between an edge of an orthographic projection of a support post on the drive backplate and an edge of an orthographic projection of the second top surface on the drive backplate is greater than 0.6 micron.

In an exemplary implementation, a support layer is further included, the support layer is on a side of the support structure away from the drive backplate and an orthographic projection of the support layer on the drive backplate is overlapped with both of the orthographic projection of the support structure on the drive backplate and the orthographic projection of the at least one light emitting unit on the drive backplate.

In an exemplary implementation, the support layer includes a thermal insulation material.

In another aspect, the present disclosure further provides a display device, including the aforementioned display panel.

In another aspect, the present disclosure further provides a method for manufacturing a display panel, including:
forming a drive backplate;
forming a support structure on the drive backplate;
the support structure supports a transfer device, and at least one light emitting unit is transferred to the drive backplate by the transfer device; an orthographic projection of the support structure on the drive backplate is not overlapped with an orthographic projection of the at least one light emitting unit on the drive backplate; and
forming a light shielding layer on the drive backplate so that the light shielding layer covers at least part of the support structure and an orthographic projection of the light shielding layer on the drive backplate is not overlapped with the orthographic projection of the at least one light emitting unit on the drive backplate; or forming at least one support post on a side of the support structure away from the drive backplate and an orthographic projection of the at least one support post on the drive backplate is not overlapped with the orthographic projection of the at least one light emitting unit on the drive backplate

In an exemplary implementation, the method for manufacturing the display panel according to an embodiment of the present disclosure further includes:
forming a support layer on a side of the support structure away from the drive backplate and an orthographic projection of the support layer on the drive backplate is overlapped with both of the orthographic projection of the support structure on the drive backplate and the orthographic projection of the at least one light emitting unit on the drive backplate.

In an exemplary implementation, the method for manufacturing the display panel according to an embodiment of the present disclosure further includes:
forming a cell-alignment substrate;
disposing the cell-alignment substrate on a side of the at least one light emitting unit away from the drive backplate.

Other aspects may become clear after the accompanying drawings and the detailed description are read and understood.

### BRIEF DESCRIPTION OF DRAWINGS

Accompanying drawings are used for providing an understanding for technical solutions of the present application and form a part of the specification, are used for explaining the technical solutions of the present application together with embodiments of the present application, and do not constitute a limitation on the technical solutions of the present application.

FIG. 1 is a schematic diagram of a planar structure of a display panel according to an embodiment of the present disclosure.

FIG. 2 is a first cross-sectional view of a display panel according to an embodiment of the present disclosure.

FIG. 3 is a cross-sectional view of a support structure and a light shielding layer in a display panel according to an embodiment of the present disclosure.

FIG. 4 is a cross-sectional view of a support post, a light shielding layer and a support structure in a display panel according to an embodiment of the present disclosure.

FIG. 5 is a second cross-sectional view of a display panel according to an embodiment of the present disclosure.

FIG. 6a is a schematic diagram of a display panel after a drive backplate is formed according to an embodiment of the present disclosure.

FIG. 6b is a schematic diagram of a display panel after a support structure and a light emitting unit are formed according to an embodiment of the present disclosure.

FIG. 6c is a schematic diagram of a display panel after a light shielding layer is formed according to an embodiment of the present disclosure.

FIG. 6d is a schematic diagram of a display panel after an encapsulation layer and a support column are formed according to an embodiment of the present disclosure.

FIG. 7 is a cross-sectional view of a support structure and a transfer device in a display panel according to an embodiment of the present disclosure.

### DETAILED DESCRIPTION

To make the objectives, technical solutions, and advantages of the present disclosure clearer, the embodiments of the present disclosure will be described in detail below with reference to the accompany drawings. It is to be noted that the implementations may be implemented in various forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the accompanying drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the accompanying drawings schematically illustrate ideal examples, and an implementation of the present disclosure is not limited to the shapes, numerical values, or the like shown in the drawings.

Ordinal numerals “first”, “second”, “third”, etc., in the specification are set not to form limitations on number but only to avoid confusion between composition elements.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the composition elements may be changed as appropriate according to a direction according to each composition element is described. Therefore, appropriate replacements based on situations are allowed, without being limited to the expressions in the specification.

In the specification, unless otherwise specified and defined, terms “mounting”, “mutual connection”, and “connection” should be understood in a broad sense. For example, a connection may be fixed connection, or detachable connection, or integral connection. It may be mechanical connection or electrical connection. It may be direct connection, or indirect connection through an intermediate, or communication inside two elements. Those of ordinary skills in the art can understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source region. It is to be noted that in the specification, the channel region refers to a region through which a current mainly flows.

In the specification, a first electrode may be a drain electrode, and a second electrode may be a source electrode. Alternatively, a first electrode may be a source electrode, and a second electrode may be a drain electrode. In cases that transistors with opposite polarities are used, or a current direction changes during operation of a circuit, or the like, functions of the “source electrode” and the “drain electrode” may sometimes be exchanged. Therefore, the “source electrode” and the “drain electrode” may be exchanged in the specification.

In the specification, “electric connection” includes connection of the composition elements through an element with a certain electric action. The “element with the certain electric action” is not particularly limited as long as electric signals between the connected composition elements may be sent and received. Examples of the “element with the certain electric action” not only include electrodes and wirings, but also include switch elements such as transistors, resistors, inductors, capacitors, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” refers to that a boundary is not defined so strictly and numerical values within process and measurement error ranges are allowed.

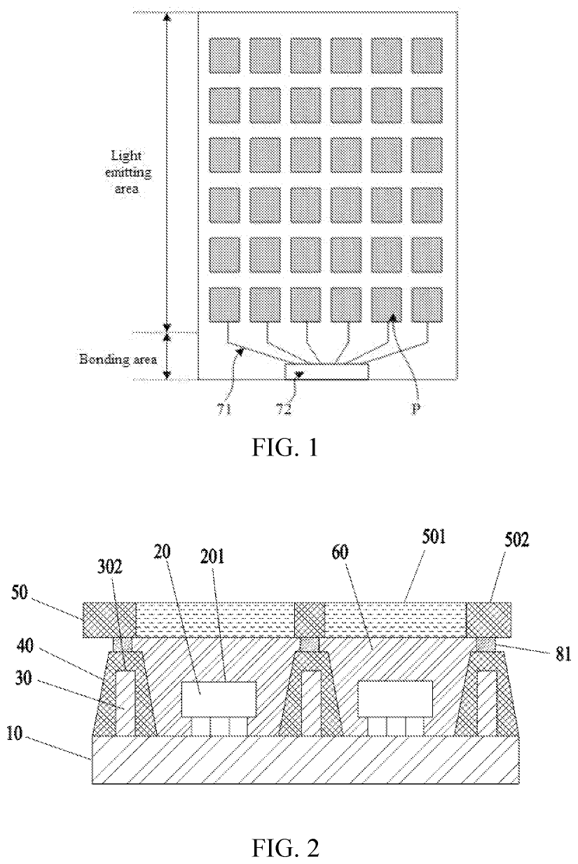

FIG. 1 is a schematic diagram of a planar structure of a display panel according to an embodiment of the present disclosure. In an exemplary embodiment, as shown in FIG. 1, the display panel may include a light emitting area. The light emitting area is configured to display images. The light emitting area includes multiple sub-pixels P arranged regularly and the sub-pixels P are configured to emit light. For example, the light emitting area includes multiple first sub-pixels, multiple second sub-pixels, and multiple third sub-pixels which are arranged regularly. The first sub-pixels may be red (R) sub-pixels, the second sub-pixels may be green (G) sub-pixels, and the third sub-pixels may be blue (B) sub-pixels. The display panel may provide an image through multiple sub-pixels P in the light emitting area.

In an exemplary implementation, the display panel may further include a bonding area which may be on one side or more sides of the light emitting area. The bonding area may include multiple leads 71 and a bonding pad 72. At least one lead 71 has one end connected to a drive circuit in at least one sub-pixel P, and the other end connected to the bonding pad 72. In an exemplary embodiment, the bonding pad 72 is configured to be connected to an external control circuit through a Flexible Printed Circuit (FPC), and the corresponding sub-pixel P is controlled to emit light by the control circuit.

In an exemplary implementation, the sub-pixel P may include a light emitting unit. The light emitting unit may include one of an organic light emitting diode (OLED), a micro light emitting diode (MLED) and a quantum dot light emitting diode (QLED). The sub-pixel P may emit light, for example red light, green light, blue light or white light, by the light-emitting unit.

In an exemplary implementation, the sub-pixel P may further include at least one drive circuit, the at least one drive circuit is connected to the light emitting unit, and the drive circuit is configured to drive the light emitting unit to emit light. The drive circuit may include a thin film transistor. The thin film transistor may include an active layer, a gate electrode, a source electrode, a drain electrode, and the like.

In an exemplary implementation, a shape of the light emitting area may be set in accordance with requirements. For example, a profile of the light emitting area may be a rectangle. A shape of the light emitting unit may also be a rectangle, which makes it easier to achieve partition control of a backlight. In some embodiments, the profile of the light emitting area may be a circle, an ellipse or a polygon shape such as a triangle, a pentagon, a hexagon or an octagon. The shape of the light emitting unit may be a circle, an ellipse, or a polygon shape such as a triangle, a pentagon, a hexagon, an octagon.

In an exemplary implementation, the display panel may be a pad display panel. In some embodiments, the display panel may employ other types of display panels as well. For example, a flexible display panel, a foldable display panel, a rollable display panel, and the like.

FIG. 2 is a first cross-sectional view of a display panel according to an embodiment of the present disclosure. FIG. 2 illustrates a cross-sectional view of two sub-pixels P. In an exemplary implementation, the display panel according to an embodiment of the present disclosure may include more sub-pixels P (see FIG. 1). Although the two sub-pixels P are shown to be adjacent to each other in FIG. 2 and an embodiment of the present disclosure is not limited thereto. That is to say, other components, for example wires, may be between the two sub-pixels P. The two sub-pixels P may not be pixels adjacent to each other. In FIG. 2, cross sections of the two sub-pixels P may not be cross sections in a same direction of the display panel.

In an exemplary implementation, as shown in FIG. 2, the display panel may include a drive backplate 10, at least one light emitting unit 20, a support structure 30 and a light shielding layer 40 in a plane perpendicular to the display panel.

In an exemplary implementation, as shown in FIG. 2, the drive backplate 10 includes a base substrate and a drive structure layer disposed on the base substrate. The drive structure layer includes at least one drive circuit, and the at least one drive circuit is connected to the at least one light emitting unit 20, and the at least one drive circuit is configured to drive the at least one light emitting unit to emit light. Each drive circuit may include a thin film transistor and the thin film transistor may include an active layer, a gate electrode, a source electrode, a drain stage and the like.

In an exemplary implementation, as shown in FIG. 2, multiple light emitting units 20 are disposed on the drive backplate 10, each of the light emitting units 20 is connected to a drive circuit in the drive backplate 10, and the light emitting units 20 are configured to emit light. A spacing between adjacent light emitting units 20 may be 15 microns to 30 microns, for example, spacing between the adjacent light emitting units 20 may be 23 microns, so that more light emitting units 20 may be provided per unit area of the display panel, and a light emission efficiency of the display panel is improved.

The display panel of this embodiment takes a case in which the light emitting units are micro light emitting diodes (MLED) as an example but the display panel of this embodiment is not limited thereto. In another embodiment, the light emitting units in the display panel may be organic light emitting diodes (OLED) or quantum dot light emitting diodes (QLED).

In an exemplary implementation, the Micro Light Emitting Diodes may include Micro Light Emitting Diodes (Micro LED) and Mini Light Emitting Diodes (Mini LED). The Micro Light Emitting Diodes have advantages of small size, high brightness, etc., and can be widely applied in a backlight module of a display device. The display device using the Micro Light Emitting Diodes can achieve high resolution, for example, the Micro Light Emitting Diode can realize a smart phone or a virtual reality screen with a 4K or 8K resolution, etc.

In virtual reality technology, response time of a micro LED display panel reaches nanosecond level, which is 1000 times faster than that of an OLED display panel with a microsecond response time.

The micro LED display panel is miniaturized, arrayed and subjected to thin film processing by using microfabrication technology, and LED chips are transferred to the drive backplate in batches by massive transfer technology.

In an exemplary implementation, a size (e.g. length) of a micro light emitting diode may be less than 50 μm, for example, a length of the micro light emitting diode may be 30 μm, and a width of the micro light emitting diode may be 15 μm.

In an exemplary implementation, as shown in FIG. 2, a support structure 30 is disposed on the drive backplate 10, and an orthographic projection of the support structure 30 on the drive backplate 10 is not overlapped with an orthographic projection of the light emitting unit 20 on the drive backplate 10. For example, the support structure 30 may be disposed around the periphery of the light emitting unit 20. The support structure 30 is configured to support a transfer device and a light emitting unit to be transferred is disposed on the transfer device.

FIG. 7 is a cross-sectional view of a support structure and a transfer device in a display panel according to an embodiment of the present disclosure. In an exemplary implementation, as shown in FIG. 7, during a transfer process of the light emitting unit 20, a side of the transfer device 90 is brought into contact with a top surface of the support structure 30, so that the support structure 30 supports the transfer device 90. A light emitting unit to be transferred is disposed in the transfer device 90, and the light emitting unit to be transferred in the transfer device 90 is transferred to the drive backplate 10 to form a light emitting unit 20 disposed on the drive backplate 10. For example, the transfer device 90 may be a medium load substrate and multiple light emitting units to be transferred are carried on the medium load substrate, and the support structure 30 supports the medium load substrate, and the light emitting units to be transferred in the medium load substrate are transferred to the drive backplate 10 by laser transfer.

In an exemplary implementation, as shown in FIG. 2, the support structure 30 has a first top surface 302 and the first top surface 302 is a surface of the support structure 30 away from the drive backplate 10. The light emitting unit 20 has a third top surface 201 and the third top surface 201 is a surface of the light emitting unit 20 away from the drive backplate 10. The first top surface 302 is on a side of the third top surface 201 away from the drive backplate 10 and when the support structure 30 supports the transfer device, the transfer device is in contact with the first top surface 302, so that a distance between the transfer device and a surface of the drive backplate 10 is larger than a height of the light emitting unit 20, thereby avoiding a problem that the light emitting unit 20 blocks the transfer device from contacting the first top surface 302, resulting in unstable support of the transfer device.

In an exemplary implementation, the support structure 30 may be an isolated structure or may be a polyline structure or may be a closed annular structure in a plane parallel to the drive backplate. For example, multiple support structures 30 may be disposed at intervals and each support structure 30 is an isolated structure. For another example, the multiple support structures 30 may be connected in turn to form a polyline structure. For yet another example, the multiple support structures 30 may be connected into a loop shape in turn to form a closed annular structure.

In an exemplary implementation, a vertical cross-sectional shape of the support structure 30 may include any one or more of the following: a triangle, a rectangle, a polygon, a circle, and an ellipse.

In an exemplary implementation, a height of the support structure 30 may be from 5 microns to 20 microns, for example the height of the support structure 30 may be from 8 microns to 10 microns.

In an exemplary implementation, the support structure 30 may be made of an organic material such as a resin.

In an exemplary implementation, as shown in FIG. 2, a light shielding layer 40 is disposed on the drive backplate 10, and the light shielding layer 40 covers at least part of the support structure 30. An orthographic projection of the light shielding layer 40 on the drive backplate 10 is not overlapped with an orthographic projection of the light emitting unit 20 on the drive backplate 10 to avoid shielding the light emitting unit 20. The light shielding layer 40 may be between adjacent light emitting units 20.

In an exemplary implementation, the light shielding layer 40 may be made of a light shielding material, for example, a black resin. The light shielding layer 40 is configured to shield light rays to avoid crosstalk between light rays emitted by the adjacent light emitting units 20.

In an exemplary implementation, an outer profile of the vertical cross section of the light shielding layer 40 may be narrower at the top and wider at the bottom, for example a positive trapezoid. Herein, the upper side of the vertical cross section of the outer profile of the light shielding layer 40 is a side of the light shielding layer 40 away from the drive backplate 10, and the lower side of the vertical cross section of the outer profile of the light shielding layer 40 is a side of the light shielding layer 40 close to the drive backplate 10. The above mentioned structure of the light shielding layer 40 has a high strength and can support a cell-alignment substrate to ensure stability of the cell-alignment substrate.

In some embodiments, the outer profile shape of the vertical cross section of the light shielding layer 40 may include any one or more of the following: a triangle, a rectangle, and an ellipse.

FIG. 3 is a cross-sectional view of a support structure and a light shielding layer in a display panel according to an embodiment of the present disclosure. In an exemplary implementation, as shown in FIG. 3, the support structure 30 has a side surface 301 and a first top surface 302 and the first top surface 302 is a surface of the support structure 30 away from the drive backplate 10. The side surface 301 is on the periphery of the first top surface 302 and connects the first top surface 302 to the drive backplate 10. The light shielding layer 40 covers the side surface 301 and the first top surface 302 of the support structure 30, and an orthographic projection of the support structure 30 on the drive backplate 10 is within an orthographic projection of the light shielding layer 40 on the drive backplate 10, thereby improving a light shielding effect of the light shielding layer 40.

In an exemplary implementation, the first top surface 302 may be a plane, i.e. the surface of the support structure 30 away from the drive backplate 10 is a plane. The first top surface 302 is in contact with the transfer device when the support structure 30 supports the transfer device, the first top surface 302 is a plane, and stability of the transfer device can be ensured. In some embodiments, the first top surface may also be a cambered surface or a concave-convex surface.

In an exemplary implementation, as shown in FIG. 3, the light shielding layer 40 has a second top surface 401 and the second top surface 401 is a surface of the light shielding layer 40 away from the drive backplate 10. The second top surface 401 of the light shielding layer 40 is on a side of the first top surface 302 of the support structure 30 away from the drive backplate 10. Herein, a distance between the second top surface 401 and the first top surface 302 is 0.5 microns to 5 microns, for example, the distance L1 between the second top surface 401 and the first top surface 302 is 1 micron to 2 microns.

In an exemplary implementation, the second top surface 401 may be a plane, a cambered surface or a concave-convex surface, i.e. the surface of the light shielding layer 40 away from the drive backplate 10 may be a plane, a cambered surface or a concave-convex surface.

In an exemplary implementation, as shown in FIG. 2, in a plane perpendicular to the display panel, the display panel may further include a cell-alignment substrate 50, the cell-alignment substrate 50 is disposed on a side of the light emitting unit 20 away from the drive backplate 10, and the cell-alignment substrate 50 is disposed in alignment with the drive backplate 10. The cell-alignment substrate 50 may have an encapsulating effect, for example the cell-alignment substrate 50 may be a glass cover plate. The cell-alignment substrate 50 may also serve as a rigid base substrate and various functional films may be manufactured on the cell-alignment substrate 50, for example the functional films may include sensors, gratings, lenses, and the like. The cell-alignment substrate 50 may also have a color conversion function and can be used in combination with the light emitting unit 20 to realize color display.

In an exemplary implementation, the embodiment of the present application takes a case in which the cell-alignment substrate 50 is a color conversion substrate as an example. As shown in FIG. 2, color display can be realized by using the cell-alignment substrate 50 in combination with the light emitting unit 20. For example, the light emitting unit 20 is a blue micro light emitting diode, and the cell-alignment substrate 50 is configured to convert the blue light emitted by the light emitting unit 20 into light with specific colors (e.g. red and green), and to transmit the blue light emitted by the light emitting unit 20 to realize color display.

In an exemplary implementation, as shown in FIG. 2, the cell-alignment substrate 50 includes a color conversion pattern 501 and a light blocking pattern 502. An orthographic projection of the color conversion pattern 501 on the drive backplate 10 is not overlapped with an orthographic projection of the light blocking pattern 502 on the drive backplate 10, and the light blocking pattern 502 separates adjacent color conversion patterns 501. The color conversion pattern 501 is configured to convert light emitted by the light emitting unit 20 into light with a specific color. The light blocking pattern 502 is configured to prevent transmission of light emitted from the light emitting unit 20 to prevent mixing of light emitted from adjacent color conversion patterns 501.

In an exemplary implementation, as shown in FIG. 2, the orthographic projection of the color conversion pattern 501 on the drive backplate 10 is overlapped with an orthographic projection of the light emitting unit 20 on the drive backplate 10, for example, the orthographic projection of the light emitting unit 20 on the drive backplate 10 is within the orthographic projection of the color conversion pattern 501 on the drive backplate 10, thereby increasing light rays incident by the light emitting unit 20 on the color conversion pattern 501.

In an exemplary implementation, as shown in FIG. 2, the color conversion pattern 501 may include a quantum dot material or a fluorescent material. For example, the color conversion pattern 501 includes a quantum dot material and a photosensitive polymer. The quantum dot material is dispersed in the photosensitive polymer and the photosensitive polymer may be an organic material (for example, a polysiloxane resin and an epoxy resin) with light transmissive properties. The quantum dot material may be excited by the light emitted by the light emitting unit 20 to isotropically emit light of a specific color (e.g. red light or green light). The color conversion pattern 501 may be manufactured by a development process.

In an exemplary implementation, as shown in FIG. 2, an orthographic projection of the light blocking pattern 502 on the drive backplate 10 is overlapped with both of the orthographic projection of the support structure 30 on the drive backplate 10 and the orthographic projection of the light shielding layer 40 on the drive backplate 10 to prevent the support structure 30 from shielding light, for example, the orthographic projection of the support structure 30 on the drive backplate 10 is within the orthographic projection of the light blocking pattern 502 on the drive backplate 10.

In an exemplary implementation, as shown in FIG. 2, the light blocking pattern 502 may be in various colors, including black or white. For example, the light blocking pattern 502 may be black. The light blocking pattern 502 may be made of a light blocking material, which may include an opaque inorganic insulation material (e.g., chromium oxide or molybdenum oxide) or an opaque organic insulation material (e.g., black resin). As another example, the light blocking pattern 502 may be made of an organic insulation material such as a white resin.

In an exemplary implementation, as shown in FIG. 2, in a plane perpendicular to the display panel, the display panel may further include an encapsulation layer 60. The encapsulation layer 60 is disposed on the drive backplate 10, and the encapsulation layer 60 covers at least part of the light emitting unit 20 and at least part of the light shielding layer 40, for example, the encapsulation layer 60 covers the entire light emitting unit 20 and side surfaces and part of the top surface of the light shielding layer 40.

In an exemplary implementation, as shown in FIG. 2, the encapsulation layer 60 includes a thermally conductive material, for example a thermally conductive resin. The encapsulation layer 60 can emit heat emitted by the light emitting unit 20 and reduce a temperature of the light emitting unit 20.

In an exemplary implementation, as shown in FIG. 2, in a plane perpendicular to the display panel, the display panel may further include at least one support post 81. The at least one support post 81 is on a side of the support structure 30 away from the drive backplate 10, and an orthographic projection of the at least one support post 81 on the drive backplate 10 is not overlapped with an orthographic projection of the light emitting unit 20 on the drive backplate 10. One end of each support post 81 may be in contact with the support structure 30 or the light shielding layer 40 and the other end of the support post 81 may be in contact with the cell-alignment substrate 50 so that the support post 81 is used for supporting the cell-alignment substrate 50.

In an exemplary implementation, as shown in FIG. 2, an orthographic projection of the support post 81 on the drive backplate 10 is overlapped with an orthographic projection of the light blocking pattern 502 in the cell-alignment substrate 50 on the drive backplate 10 and the support post 81 may be in contact with the light blocking pattern 502 in the cell-alignment substrate 50 to prevent the support post 81 from shielding light.

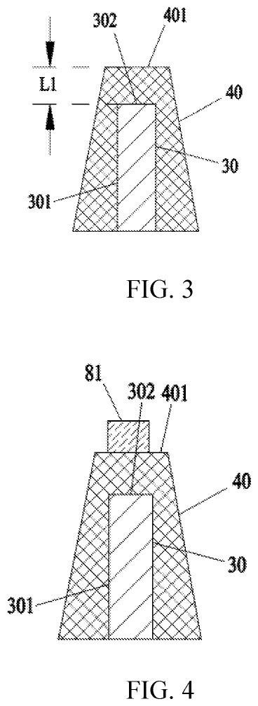

FIG. 4 is a cross-sectional view of a support post, a light shielding layer and a support structure in a display panel according to an embodiment of the present disclosure. In an exemplary implementation, as shown in FIG. 4, the support structure 30 has a first top surface 302 and the first top surface 302 is a surface of the support structure 30 away from the drive backplate 10. A side surface 301 is on the periphery of the first top surface 302 and connects the first top surface 302 to the drive backplate 10. The light shielding layer 40 covers the side surface 301 and the first top surface 302 of the support structure 30. The light shielding layer 40 has a second top surface 401 and the second top surface 401 is a surface of the light shielding layer 40 away from the drive backplate 10. A support post 81 is disposed on the second top surface 401 and is in contact with the second top surface 401. An orthographic projection of the support post 81 on the drive backplate 10 is overlapped with an orthographic projection of the second top surface 401 on the drive backplate 10, for example, the orthographic projection of the support post 81 on the drive backplate 10 is within the orthographic projection of the second top surface 401 on the drive backplate 10.

In an exemplary implementation, as shown in FIG. 4, a distance L2 between an edge of the orthographic projection of the support post 81 on the drive backplate 10 and an edge of the orthographic projection of the second top surface 401 on the drive backplate 10 is greater than 0.6 micron, for example, a width of the orthographic projection of the support post 81 on the drive backplate 10 is 5 microns, a width of the orthographic projection of the second top surface 401 on the drive backplate 10 is 6.2 microns, and the distance L2 between the edge of the orthographic projection of the support post 81 on the drive backplate 10 and the edge of the orthographic projection of the second top surface 401 on the drive backplate 10 is greater than 0.6 micron.

In an exemplary implementation, the support post 81 may be a columnar body and the planar shape of the columnar body may be a rectangle or may be a circle.

In an exemplary implementation, in a plane perpendicular to the drive backplate, the cross-sectional shape of the support post 81 may include any one or more of the following: a triangle, a rectangle, and a trapezoid.

In an exemplary implementation, the support post 81 may be made of an organic material, for example, a resin.

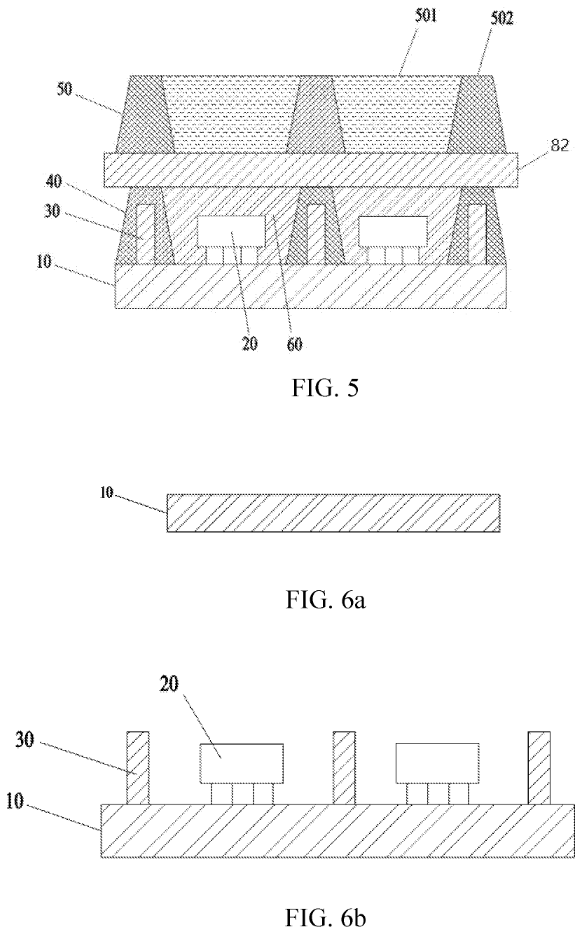

FIG. 5 is a second cross-sectional view of a display panel according to an embodiment of the present disclosure. In an exemplary implementation, as shown in FIG. 5, in a plane perpendicular to the display panel, the display panel may further include a support layer 82 and the support layer 82 is on a side of the support structure 30 away from the drive backplate 10. The support layer 82 has a layered structure, and an orthographic projection of the support layer 82 on the drive backplate is overlapped with each of an orthographic projection of the support structure 30 on the drive backplate, an orthographic projection of the light shielding layer 40 on the drive backplate, and an orthographic projection of the light emitting unit 20 on the drive backplate, for example, all of the orthographic projection of the support structure 30 on the drive backplate, the orthographic projection of the light shielding layer 40 on the drive backplate, and the orthographic projection of the light emitting unit 20 on the drive backplate are within the orthographic projection of the support layer 82 on the drive backplate. A surface of the support layer 82 close to the drive backplate 10 may be in contact with the support structure 30 or the light shielding layer 40, a surface of the support layer 82 away from the drive backplate 10 may be in contact with the cell-alignment substrate 50, and the support layer 82 is configured to support the cell-alignment substrate 50.

In an exemplary implementation, as shown in FIG. 5, a thickness of the support layer 82 may be 1 micron to 10 microns, for example 3 microns to 5 microns.

In an exemplary implementation, as shown in FIG. 5, the color conversion pattern 501 of the cell-alignment substrate 50 may include a quantum dot material and an ink material, the quantum dot material is dispersed in the ink material, and the ink material may be a material with light transmissive properties. The quantum dot material may be excited by the light emitted by the light emitting unit 20 to isotropically emit light of a specific color (e.g. red light or green light). The color conversion pattern 501 may be manufactured by an inkjet printing process.

In an exemplary implementation, as shown in FIG. 5, the support layer 82 may include a thermal insulation material, for example a polyurethane resin. Since the ink material in the color conversion pattern 501 has a low degree of heat resistance (for example, 100 degrees Celsius), the support layer 82 can prevent the heat emitted by the light emitting unit 20 from being transferred to the color conversion pattern 501 of the cell-alignment substrate 50, thereby avoiding damage to the color conversion pattern 501 caused by a high temperature.

As can be seen from the above-described display panel, in the display panel according to the exemplary embodiment of the present disclosure, by providing the support structure, the support structure supports the transfer device, so that the light emitting unit to be transferred in the transfer device is transferred to the drive backplate; by providing the light shielding layer, crosstalk between the light rays emitted by adjacent light emitting units is avoided; by covering at least part of the support structure using the light shielding layer, there is no need to eliminate the support structure and the process flow is simplified; the support structure covered by the light shielding layer also has a light shielding function, which does not occupy space of the display panel; and the support structure and the light shielding layer can also be used as a part of a structure supporting the cell-alignment substrate.

An embodiment of the present disclosure further provides a method for manufacturing a display panel, including:
forming a drive backplate;
forming a support structure on the drive backplate;
the support structure supports a transfer device, and at least one light emitting unit is transferred to the drive backplate through the transfer device; an orthographic projection of the support structure on the drive backplate is not overlapped with an orthographic projection of the light emitting unit on the drive backplate; and
a light shielding layer is formed on the drive backplate so that the light shielding layer covers at least part of the support structure and an orthographic projection of the light shielding layer on the drive backplate is not overlapped with the orthographic projection of the light emitting unit on the drive backplate.

In an exemplary implementation, the method for manufacturing the display panel of an embodiment of the present disclosure further includes:
forming at least one support post on a side of the support structure away from the drive backplate; an orthographic projection of the support post on the drive backplate is not overlapped with the orthographic projection of the light emitting unit on the drive backplate.

In an exemplary implementation, the method for manufacturing the display panel of an embodiment of the present disclosure further includes:
forming a support layer on a side of the support structure away from the drive backplate and an orthographic projection of the support layer on the drive backplate is overlapped with both of the orthographic projection of the support structure on the drive backplate and the orthographic projection of the light emitting unit on the drive backplate.

In an exemplary implementation, the method for manufacturing the display panel of an embodiment of the present disclosure further includes:
forming a cell-alignment substrate;
the cell-alignment substrate is provided on a side of the light emitting unit away from the drive backplate.

In an exemplary implementation, the cell-alignment substrate is formed on a side of the second support structure away from the drive backplate.

In an exemplary implementation, forming the cell-alignment substrate includes:
forming the cell-alignment substrate by a development process or an inkjet printing process.

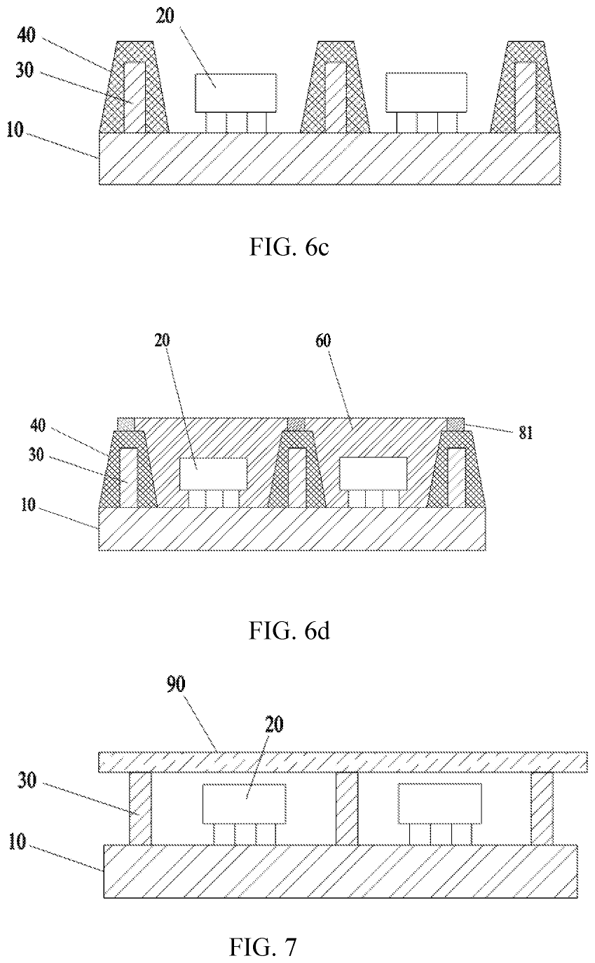

Hereinafter, an exemplary description will be given for a structure and a manufacturing process of a display panel with reference to FIG. 6a to FIG. 6d.

A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation and chemical vapor deposition, the coating may be any one or more of spray coating, spin coating and inkjet printing, and the etching may be any one or more of dry etching and wet etching, the present disclosure is not limited thereto. A “thin film” refers to a layer of thin film made of a material on a base substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

In an exemplary implementation, the manufacturing process of the display panel may include the following:

### (1) Forming a Drive Backplate

In an exemplary embodiment, forming the drive backplate includes: forming a drive structure layer on a base substrate and the base substrate and the drive structure layer in combination form the drive backplate 10 as shown in FIG. 6a.

In an exemplary embodiment, the base substrate may be a rigid base substrate or a flexible base substrate. For example, the rigid base may be made of, but not limited to, one or more of glass and quartz. The flexible base may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers.

In an exemplary embodiment, the drive structure layer includes at least one drive circuit, each drive circuit may include a thin film transistor, and the thin film transistor may include an active layer, a gate electrode, a source electrode, a drain electrode, and the like.

### (2) Forming a Support Structure and a Light Emitting Unit

In an exemplary embodiment, forming the support structure and the light emitting unit includes:
depositing a layer of a first organic material thin film on the drive backplate 10 and patterning the first organic material thin film by a patterning process, so that the first organic material thin film forms the support structure 30 provided on the drive backplate 10;
on the drive backplate 10 forming the aforementioned pattern, placing a transfer device provided with the light emitting unit to be transferred on the support structure 30, the transfer device is supported by the support structure 30, and the light emitting units to be transferred on the transfer device are transferred to the drive backplate 10 to form the light emitting unit 20 provided on the drive backplate 10, as shown in FIG. 6b. Herein, an orthographic projection of the support structure 30 on the drive backplate 10 is not overlapped with an orthographic projection of the light emitting unit 20 on the drive backplate 10.

### (3) Forming a Light Shielding Layer

In an exemplary embodiment, forming the light shielding layer includes: forming, through a development process or an inkjet printing process, the light shielding layer 40 provided on the drive backplate 10 on which the aforementioned pattern is formed the light shielding layer 40 covers at least part of the support structure 30, and an orthographic projection of the light shielding layer 40 on the drive backplate 10 is not overlapped with the orthographic projection of the light emitting unit 20 on the drive backplate 10, as shown in FIG. 6c.

### (4) Forming an Encapsulation Layer and a Support Post

In an exemplary embodiment, forming the encapsulation layer and the support post includes: depositing a layer of a thermal conductive material thin film on the drive backplate 10, on which the aforementioned pattern is formed, patterning the thermal conductive material thin film by a patterning process, so that the thermal conductive material thin film forms the encapsulation layer 60 provided on the drive backplate 10 and the encapsulation layer 60 covers at least part of the light emitting unit and at least part of the light shielding layer; forming a layer of a second organic material thin film on the encapsulation layer 60 and patterning the second organic material thin film by a patterning process, so that the second organic material thin film forms the support post 81 provided on the light shielding layer 40 and an orthographic projection of the support post 81 on the drive backplate 10 is not overlapped with the orthographic projection of the light emitting unit 20 on the drive backplate 10, as shown in FIG. 6d. Herein, the light shielding layer 40 has a second top surface, the support post 81 is disposed on the second top surface 401, and the support post 81 is in contact with the second top surface 401.

### (5) Forming a Cell-Alignment Substrate

In an exemplary embodiment, forming the cell-alignment substrate includes manufacturing the cell-alignment substrate 50 by a development process and cell-aligning the cell-alignment substrate 50 with a drive backplate 10, on which the aforementioned pattern is formed, so that a light blocking pattern in the cell-alignment substrate 50 is in contact with the support post 81 and the support post 81 supports the cell-alignment substrate 50, as shown in FIG. 2.

In some embodiments, the cell-alignment substrate may be manufactured by an inkjet printing process.

The manufacturing process of the display panel according to the exemplary embodiment of the present disclosure may be compatible well with an existing manufacturing process, and the process is simple to implement and is easy to carry out, and has a high production efficiency, a low production cost and a high yield.

The present disclosure further provides a display apparatus, including the display panel of the aforementioned exemplary embodiment. The display device may be any product or component with a display function, such as a mobile phone, a tablet computer, a television, a display, a laptop computer, a digital photo frame, or a navigator.

Although the implementations disclosed in the present disclosure are described as above, the described contents are only implementations which are used for facilitating the understanding of the present disclosure, but are not intended to limit the present disclosure. Any skilled person in the art to which the present disclosure pertains may make any modifications and variations in forms and details of implementations without departing from the spirit and scope of the present disclosure. However, the patent protection scope of the present disclosure should be subject to the scope defined by the appended claims.

1. A display panel, comprising:
a drive backplate;
at least one light emitting unit disposed on the drive backplate;
a support structure, disposed on the drive backplate, wherein an orthographic projection of the support structure on the drive backplate is not overlapped with an orthographic projection of the at least one light emitting unit on the drive backplate; and
a light shielding layer disposed on the drive backplate, wherein the light shielding layer covers at least part of the support structure and an orthographic projection of the light shielding layer on the drive backplate is not overlapped with the orthographic projection of the at least one light emitting unit on the drive backplate.

2. The display panel according to claim 1, wherein the support structure has a side surface and a first top surface and the light shielding layer covers the side surface and the first top surface of the support structure.

3. The display panel according to claim 2, wherein the light shielding layer has a second top surface and the second top surface is on a side of the first top surface away from the drive backplate.

4. The display panel according to claim 3, wherein a distance between the second top surface and the first top surface is 1 micron to 2 microns.

5. The display panel according to claim 1, wherein the support structure has a first top surface, the at least one light emitting unit has a third top surface, and the first top surface is on a side of the third top surface away from the drive backplate.

6. The display panel according to claim 1, wherein an outer profile of a vertical cross section of the light shielding layer is narrower at top and wider at bottom.

7. The display panel according to claim 1, further comprising a cell-alignment substrate, wherein the cell-alignment substrate is disposed on a side of the at least one light emitting unit away from the drive backplate.

8. The display panel according to claim 7, wherein the cell-alignment substrate comprises a light blocking pattern, the orthographic projection of the support structure on the drive backplate is overlapped with an orthographic projection of the light blocking pattern on the drive backplate.

9. The display panel according to claim 8, wherein the cell-alignment substrate further comprises a color conversion pattern, an orthographic projection of the color conversion pattern on the drive backplate is not overlapped with the orthographic projection of the light blocking pattern on the drive backplate, and the orthographic projection of the color conversion pattern on the drive backplate is overlapped with the orthographic projection of the at least one light emitting unit on the drive backplate.

10. The display panel according to claim 9, wherein the color conversion pattern comprises a quantum dot material or a fluorescent material.

11. The display panel according to claim 1, further comprising an encapsulation layer, wherein the encapsulation layer is disposed on the drive backplate and the encapsulation layer covers at least a part of the at least one light emitting unit.

12. The display panel according to claim 11, wherein the encapsulation layer comprises a thermally conductive material.

13. The display panel according to claim 1, further comprising at least one support post, wherein the at least one support post is on a side of the support structure away from the drive backplate and an orthographic projection of the at least one support post on the drive backplate is overlapped with the orthographic projection of the at least one light emitting unit on the drive backplate.

14. The display panel according to claim 13, wherein the support structure has a first top surface, the light shielding layer covers the first top surface of the support structure, the light shielding layer has a second top surface, and the at least one support post is disposed on the second top surface.

15. The display panel according to claim 14, wherein a distance between an edge of the orthographic projection of the at least one support post on the drive backplate and an edge of an orthographic projection of the second top surface on the drive backplate is greater than 0.6 microns.

16. The display panel according to claim 1, further comprising a support layer, wherein the support layer is on a side of the support structure away from the drive backplate and an orthographic projection of the support layer on the drive backplate is overlapped with both of the orthographic projection of the support structure on the drive backplate and the orthographic projection of the at least one light emitting unit on the drive backplate.

17. The display panel according to claim 16, wherein the support layer comprises a thermal insulation material.

18. A display device, comprising the display panel according to claim 1.

19. A method for manufacturing a display panel, comprising:
forming a drive backplate;
forming a support structure on the drive backplate;
wherein the support structure supports a transfer device, and at least one light emitting unit is transferred to the drive backplate by the transfer device; an orthographic projection of the support structure on the drive backplate is not overlapped with an orthographic projection of the at least one light emitting unit on the drive backplate;
forming a light shielding layer on the drive backplate so that the light shielding layer covers at least part of the support structure and an orthographic projection of the light shielding layer on the drive backplate is not overlapped with the orthographic projection of the at least one light emitting unit on the drive backplate.

20. The method for manufacturing the display panel according to claim 19, further comprising:
forming at least one support post on a side of the support structure away from the drive backplate and an orthographic projection of the at least one support post on the drive backplate is not overlapped with the orthographic projection of the at least one light emitting unit on the drive backplate; or, a support layer is formed on the side of the support structure away from the drive backplate and an orthographic projection of the support layer on the drive backplate is overlapped with both of the orthographic projection of the support structure on the drive backplate and the orthographic projection of the at least one light emitting unit on the drive backplate; or
the method further comprises:
forming a cell-alignment substrate;
wherein the cell-alignment substrate is disposed on a side of the at least one light emitting unit away from the drive backplate.

21. (canceled)
